(19) United States
(12) Patent Application Publication
(10) Pub. No.: US 2006/0284283 A1
(43) Pub. Date: Dec. 21, 2006

(54) Semiconductor device and manufacturing method thereof

(75) Inventors: Tetsuya Nakamura, Mie (JP); Kazuyuki Sawada, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/354,854

(22) Filed: Feb. 16, 2006

(30) Foreign Application Priority Data
Jun. 20, 2005 (JP) 2005-179672

(51) Int. Cl. H01L 29/861; H01L 21/20

(52) U.S. Cl. 257/603; 438/380; 257/E29.335

(57) ABSTRACT

A -Zener diode includes a first conductivity type semiconductor region and a second conductivity type semiconductor region which form pn junction, an insulating film for covering the junction part of the semiconductor regions, a first electrode electrically connected with the first conductivity type semiconductor region, and a second electrode electrically connected with the second conductivity type semiconductor region. The second conductivity type semiconductor region has an impurity concentration distribution which is a combination of a first impurity concentration distribution having first diffusion depth and first peak concentration and a second impurity concentration distribution having second diffusion depth shallower than the first diffusion depth and second peak concentration higher than the first peak concentration. The first impurity concentration distribution is higher than the second impurity concentration distribution in concentration at the junction part.

### BACKGROUND ART

1. Field of the Invention

The present invention relates to a Zener diode, and more particularly relates to a Zener diode incorporated in a semiconductor deice having a MOS (metal oxide semiconductor) transistor or the like.

2. Description of the Prior Art

In forming an impurity diffusion region in a semiconductor deice by ion implantation, thermal treatment is carried out for activating and diffusing the implanted impurity. Meanwhile, in association with miniaturization in element size, the impurity diffusion region must be miniaturized, and accordingly, the temperature for the thermal treatment must be lowered for preventing the implanted impurity from excessive diffusion.

For miniaturization in element size of the above semiconductor device, a small-sized and large-current capacity Zener diode has been proposed as a miniaturized Zener diode (see Japanese Utility Model Application Laid-open Gazette No. 6-2720A, for example). FIG. 25 shows a sectional structure of the conventional Zener diode disclosed in the Japanese Utility Model Application Laid-open Gazette No. 6-2720A. As shown in FIG. 25, an n⁺ impurity region 202 and a p⁺ impurity region 203 are formed so as to form pn junction in a semiconductor substrate 201. An insulating film 204 in which openings are formed correspondingly to respective electrode contact parts 205 of the n⁺ impurity region 202 and the p⁺ impurity region 203 is formed on the semiconductor substrate 201.

The n⁺ impurity region 202 is larger than the p⁺ impurity region in size in the plane direction and the depth direction. This allows the p⁺n⁺ junction plane to be flat, suppressing a local increase in current density. Thus, a small-sized large-current capacity Zener diode can be obtained.

### SUMMARY OF THE INVENTION

However; when low-temperature thermal treatment is carried out for restraining impurity diffusion for the purpose of element size miniaturization in the conventional Zener diode shown in FIG. 25, the diffusion depth of the impurity becomes shallow to increase impurity concentration at the surface of the substrate though the impurity diffusion is retrained. This increases the concentration at the pn junction part on which leakage current concentrates, inviting an increase in leakage current. While, when the impurity concentration is lowered for preventing leakage current from increasing, the resistance of a diffusion layer (an impurity region) increases and the contact resistance between an electrode and the diffusion layer also increases.

In view of the above problems, the present invention has its object of providing a Zener diode and a method for manufacturing it which can prevent leakage current and resistance of an impurity region from increasing under miniaturization.

To attain the above object, a first semiconductor device according to the present invention is a semiconductor including a semiconductor substrate and a Zener diode formed on the semiconductor substrate, wherein the Zener diode includes: a first conductivity type semiconductor region and a second conductivity type semiconductor region which are formed so as to form pn junction in the semiconductor substrate; an insulating film for covering a junction part of the first conductivity type semiconductor region and the second conductivity type semiconductor region; a first electrode formed on the first conductivity type semiconductor region so as to be electrically connected with the first conductivity type semiconductor region; and a second electrode formed on the second conductivity type semiconductor region so as to be electrically connected with the second conductivity type semiconductor region, wherein the second conductivity type semiconductor region has an impurity concentration distribution which is a combination of a first impurity concentration diffusion distribution having first diffusion depth and first peak concentration and a second impurity diffusion distribution having second diffusion depth shallower than the first diffusion depth and second peak concentration higher than the first peak concentration, and the first impurity concentration distribution is higher than the second impurity concentration distribution in concentration at the junction part.

In the first semiconductor device according to the present invention, the second conductivity type semiconductor region has the impurity concentration distribution which is a combination of the first impurity concentration distribution having lower concentration and deeper diffusion depth and the second impurity concentration distribution having higher concentration and shallower diffusion depth, and the concentration at the junction part of the first conductivity type semiconductor region and the second conductivity type semiconductor region is defined by the low-concentration first impurity concentration distribution in the second conductivity type semiconductor region. Accordingly, the pn junction part, on which leakage current concentrates, can have impurity concentration lower than that of the conventional one even in the case where the impurity layers of the Zener diode are formed by low-temperature thermal treatment for the purpose of element size miniaturization, reducing leakage current. Also, the impurity concentration in the vicinity of the substrate surface in the second conductivity type semiconductor region is defined by the high-concentration second impurity concentration distribution, resulting in a lowering in resistance of the second conductivity type semiconductor region and a lowering in contact resistance between the second conductivity type semiconductor region and the electrode.

A second semiconductor device according to the present invention is a semiconductor integrated circuit device in which a Zener diode and a CMOS (complementary metal oxide semiconductor) circuit or the like are hybrided on a single semiconductor substrate, wherein each of a p⁺ source region and a p⁺ drain region of a p-channel field effect transistor and a p⁺ anode region of the Zener diode has an impurity concentration distribution which is a combination of a first impurity concentration distribution and a second impurity concentration distribution having diffusion depth and peak concentration shallower and higher than the first impurity concentration distribution, and the first impurity concentration distribution is higher than the second impurity concentration distribution in concentration at a junction part of the p⁺ anode region and an n⁺ cathode region.

In the second semiconductor device according to the present invention, similar to the first semiconductor device, the pn junction part, on which leakage current concentrates, can have impurity concentration lower than the conventional one even in the case where impurity layers of the Zener diode are formed by low-temperature thermal treatment for the purpose of element size miniaturization, reducing leakage current of the Zener diode. Accordingly, this prevents an increase in impurity concentration at the pn junction part by low-temperature thermal treatment, and hence, the respective p⁺ impurity layers in the source region and the drain region of the p-channel filed effect transistor can be formed by low-temperature thermal treatment, implementing further element size miniaturization with impurity diffusion restrained. Also, the impurity concentration in the vicinity of the substrate surface in the p⁺ impurity layer in the anode region of the Zener diode is defined by the high-concentration second impurity concentration distribution, lowering both the resistance of the anode region and the contact resistance between the anode region and the electrode.

In manufacturing the second semiconductor device of the present invention, that is, a semiconductor integrated circuit device in which a Zener diode and a COMS circuit or the like are hybrided on a single substrate, the impurity layers in the cathode region and the anode region of the Zener diode are formed in the same step as the step of forming the impurity layers of the source regions and the drain regions of the CMOS circuit, so that the Zener diode can be hybrided without increasing the number of manufacturing steps.

As described above, in the Zener diode formed on the semiconductor substrate according to the present invention, the pn junction part, on which leakage current concentrates, can have low concentration, reducing leakage current.

Further, according to the present invention, in the semiconductor integrated circuit device in which a Zener diode and CMOS circuit or the like are hybrided on a single substrate, the pn junction part, on which leakage current of the Zener diode concentrates, can have low concentration, reducing leakage current of the Zener diode. Further, the p⁺ impurity layers in the source region and the drain region of the p-channel field effect transistor can be formed at low temperature, implementing element size reduction while restraining impurity diffusion. Also, the impurity layers in the cathode region and the anode region of the Zener diode are formed in the same step as the step of forming the impurity layers in the source region and the drain region of the CMOS circuit, enabling hybridization of the Zener diode without increasing the number of manufacturing steps.

In consequence, the semiconductor device and the semiconductor device manufacturing method according to the present invention are useful for realizing a low-leakage Zener diode. Particularly, in the case where the present invention is applied to a semiconductor integrated circuit device in which a Zener diode and a CMOS circuit or the like are hybrided on a single substrate, the present invention is much useful because an effect of element size miniaturization with impurity diffusion restrained and an effect of hybridization of a Zener diode without increasing the number of manufacturing steps can be obtained in addition to the effect of realizing a low-leakage Zener diode.

### BRIEF DESCRIPTION OF THE DRAWINGS

FIG. 1 is a section showing a structure of a semiconductor device according to Embodiment 1 of the present invention.

FIG. 2 is a graph showing each concentration profile of an n-type semiconductor layer and p-type semiconductor layers of a Zener diode of the semiconductor device according to Embodiment 1 of the present invention.

FIG. 3 is a section showing one step in a semiconductor device manufacturing method according to Embodiment 1 of the present invention.

FIG. 4 is a section showing one step in the semiconductor device manufacturing method according Embodiment 1 of the present invention.

FIG. 5 is a section showing one step in the semiconductor device manufacturing method according Embodiment 1 of the present invention.

FIG. 6 is a section showing one step in the semiconductor device manufacturing method according Embodiment 1 of the present invention.

FIG. 7 is a section showing one step in the semiconductor device manufacturing method according Embodiment 1 of the present invention.

FIG. 8 is a section showing one step in the semiconductor device manufacturing method according Embodiment 1 of the present invention.

FIG. 9 is a section showing one step in the semiconductor device manufacturing method according Embodiment 1 of the present invention.

FIG. 10 is a section showing one step in the semiconductor device manufacturing method according Embodiment 1 of the present invention.

FIG. 11 is a section showing a structure of a semiconductor device according to Embodiment 2 of the present invention.

FIG. 12 is a graph showing each concentration profile of an n-type semiconductor layer and p-type semiconductor layers of a Zener diode of the semiconductor device according to Embodiment 2 of the present invention.

FIG. 13 is a section showing one step in a semiconductor device manufacturing method according to Embodiment 2 of the present invention.

FIG. 14 is a section showing one step in the semiconductor device manufacturing method according to Embodiment 2 of the present invention.

FIG. 15 is a section showing one step in the semiconductor device manufacturing method according to Embodiment 2 of the present invention.

FIG. 16 is a section showing one step in the semiconductor device manufacturing method according to Embodiment 2 of the present invention.

FIG. 17 is a section showing one step in the semiconductor device manufacturing method according to Embodiment 2 of the present invention.

FIG. 18 is a section showing one step in the semiconductor device manufacturing method according to Embodiment 2 of the present invention.

FIG. 19 is a section showing one step in the semiconductor device manufacturing method according to Embodiment 2 of the present invention.

FIG. 20 is a section showing one step in the semiconductor device manufacturing method according to Embodiment 2 of the present invention.

FIG. 21 is a section showing one step in the semiconductor device manufacturing method according to Embodiment 2 of the present invention.

FIG. 22 is a section showing one step in the semiconductor device manufacturing method according to Embodiment 2 of the present invention.

FIG. 23 is a section showing one step in the semiconductor device manufacturing method according to Embodiment 2 of the present invention.

FIG. 24 is a section showing one step in the semiconductor device manufacturing method according to Embodiment 2 of the present invention.

FIG. 25 is a section showing a structure of a conventional Zener diode.

### DESCRIPTION OF THE PREFERRED EMBODIMENTS

### Embodiment 1

A semiconductor device and a method for manufacturing it according to Embodiment 1 of the present invention will be described below with reference to the accompanying drawings.

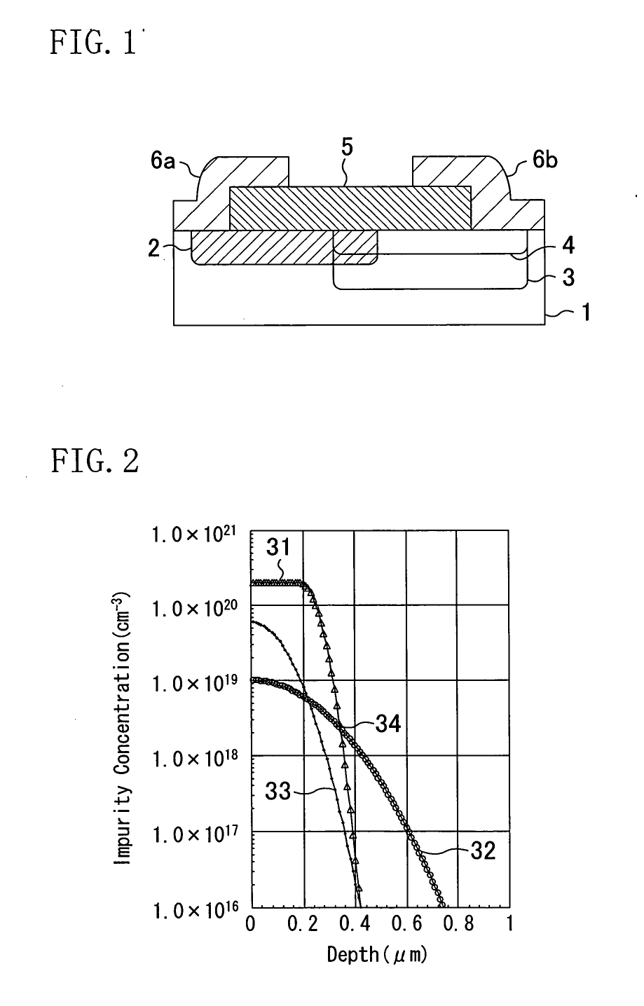

FIG. 1 is a section showing a structure of a semiconductor device according to Embodiment 1, specifically a semiconductor device having a Zener diode formed on a semiconductor substrate.

As shown in FIG. 1, the Zener diode of the present embodiment includes an n-type semiconductor layer 2 and p-type semiconductor layers of a lower layer 3 and an upper layer 4 which are formed to form pn junction in a semiconductor substrate 1, an insulating film 5 for covering a junction part (the pn junction) of the n-type semiconductor layer 2 and the p-type semiconductor layers 3 and 4, a cathode electrode wiring 6a formed on a part of the n-type semiconductor layer 2 where the insulating film 5 is not formed so as to be electrically connected with the n-type semiconductor layer 2, and an anode electrode wiring 6b formed on a part of the p-type semiconductor layer 4 where the insulating film 5 is not formed so as to be electrically connected with the p-type semiconductor layer 4. Accordingly, the pn junction part is located between the cathode electrode wiring 6a and the anode electrode wiring 6b.

Specifically, the semiconductor substrate 1 is formed of an n-type silicon substrate having an impurity concentration of approximately 1×10¹⁶ to 1×10¹⁷ cm⁻³, for example. The impurity concentration distribution of the n-type semiconductor layer 2 is defined dominantly by a concentration profile of which peak concentration at the substrate surface portion is approximately 1×10²⁰ to 5×10²⁰ cm⁻³ and of which diffusion depth is approximately 0.3 to 0.5 μm, for example. The p-type impurity concentration distribution of the p-type semiconductor layer 3 is defined dominantly by a concentration profile of which peak concentration at the substrate surface portion is approximately 7×10¹⁸ to 3×10¹⁹ cm⁻³ and of which diffusion depth is approximately 0.6 to 0.9 μm, for example. The p-type impurity concentration distribution of the p-type semiconductor layer 4 is defined dominantly by a concentration profile of which peak concentration at the substrate surface portion is approximately 3×10¹⁹ to 1×10²⁰ cm⁻³ and of which diffusion depth is approximately 0.3 to 0.5 μm, for example. The n-type impurity concentration distribution of the n-type semiconductor layer 2 and the p-type impurity concentration distributions of the p-type semiconductor layers 3 and 4 overlap with each other in the range of approximately 1 to 2 μm in the horizontal direction. Further, the impurity concentration at the pn junction part of the n-type semiconductor layer 2 and the p-type semiconductor layers 3, 4 (where the n-type impurity concentration and the p-type impurity concentration are in equilibrium) is approximately 1×10¹⁸ to 5×10¹⁸ cm⁻³, for example. The insulating film 5 is formed of a silicon oxide film having a thickness of approximately 100 nm to 2 μm, for example. The cathode electrode wiring 6a and the anode electrode wiring 6b are made of Al—Si—Cu alloy of which main component is Al and which has approximately the same thermal conductivity as Al, for example.

One of the significant features of the present embodiment lies in that the p-type semiconductor region formed of the p-type semiconductor layer 3 and the p-type semiconductor layer 4 has an impurity concentration distribution which is a combination of a first p-type impurity concentration distribution (defining the impurity concentration distribution of the p-type semiconductor layer 3) having first diffusion depth and first peak concentration and a second p-type impurity concentration distribution (defining the impurity concentration distribution of the p-type semiconductor layer 4) having second diffusion depth shallower than the first diffusion depth and second peak concentration higher than the first peak concentration. Wherein, the first p-type impurity concentration distribution is higher than the second p-type impurity concentration distribution in concentration at the pn junction part.

In the present embodiment, the region where the concentration in the first p-type impurity concentration distribution is higher than the concentration in the second p-type impurity concentration distribution serves as the p-type semiconductor layer 3 while the region where the concentration of the second p-type impurity concentration distribution is higher than the concentration in the first p-type impurity concentration distribution serves as the p-type semiconductor layer 4. Accordingly, the pn junction part is a junction part of the low-concentration p-type semiconductor layer 3 and the n-type semiconductor layer 2. The second p-type impurity concentration distribution may not reach the pn junction part.

FIG. 2 shows each example of the concentration profile of the n-type semiconductor layer (in a cathode region) 2 and the concentration profiles of the p-type semiconductor layers (in an anode region) 3 and 4. Wherein, in FIG. 2, reference numeral 31 denotes the concentration profile of the n-type semiconductor layer 2, that is, the n-type impurity concentration distribution, 32 denotes the first p-type impurity concentration distribution that defines the concentration profile of the p-type semiconductor layer 3, 33 denotes the second p-type impurity concentration distribution that defines the concentration profile of the p-type semiconductor layer 4, and 34 denotes the impurity concentration at the pn junction part.

In the above-described Zener diode of the present embodiment, the concentration at the pn junction part is defined by the p-type semiconductor layer 3 in the anode region, which has low concentration and deep diffusion depth. Accordingly, even in the case where the impurity layers are formed by low-temperature thermal treatment for the purpose of element size miniaturization, the pn junction part, on which leakage current concentrates, can have low impurity concentration (specifically, 1×10¹⁸ to 5×10¹⁸ cm⁻³) compared with a conventional one, resulting in a reduction in leakage current. Further, the p-type semiconductor layer 4 having a peak concentration of approximately 3×10¹⁹ to 1×10²⁰ cm⁻³ is formed in the vicinity of the substrate surface in the anode region, so that the resistance of the anode region is lowered and an increase in contact resistance between the anode region and the electrode can be suppressed.

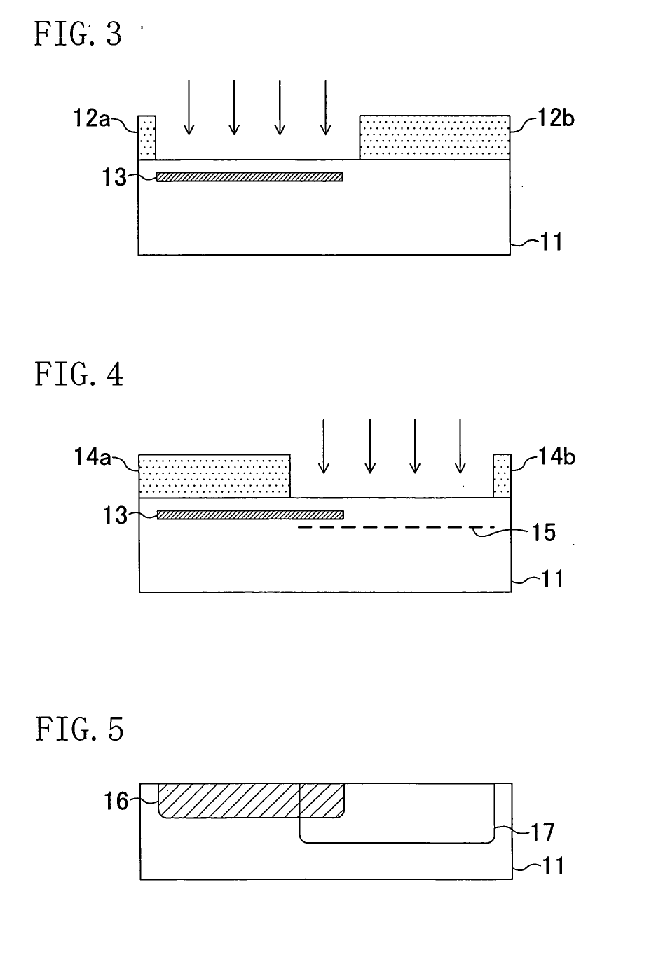

A semiconductor device manufacturing method according to Embodiment 1 will be described below with reference to FIG. 3 to FIG. 10.

FIG. 3 to FIG. 10 are sections showing respective steps in a semiconductor device manufacturing method (specifically, a Zener diode) according to Embodiment 1.

First, as shown in FIG. 3, resist films 12a and 12b of which part is opened correspondingly to a cathode region are formed and pattered on a semiconductor substrate 11 formed of an n-type silicon substrate having an impurity concentration of, for example, approximately 1×10¹⁶ to 1×10¹⁷ cm⁻³, and then, an n-type impurity 13 such as As is ion implanted into the cathode region of the semiconductor substrate 11 with the use of the resist films 12a and 12b as a mask. As to the conditions for the ion implantation, the dose amount is set to, for example, approximately 5.0×10¹⁵ to 1.1×10¹⁶ cm⁻² and the acceleration energy is set to, for example, approximately 60 keV.

Next, as shown in FIG. 4, after the resist films 12a and 12b are removed, resist films 14a and 14b of which part is opened correspondingly to an anode region are formed and patterned on the semiconductor substrate 11, and then, a p-type impurity 15 such as B is ion implanted into the anode region of the semiconductor substrate 11 with the use of the resist films 14a and 14b as a mask. As to the conditions for the ion implantation, the dose amount is set to, for example, approximately 1.0×10¹⁴ to 5.0×10¹⁴ cm⁻² and the acceleration energy is set to, for example, approximately 50 keV.

Subsequently, after the resist films 14a and 14b are removed, the semiconductor substrate 11 is subjected to thermal treatment at a temperature of, for example, approximately 1000° C. for approximately 20 to 30 minutes in an atmosphere of, for example, N₂ to diffuse the implanted n-type impurity 13 and the implanted p-type impurity 15, thereby forming an n-type impurity layer 16 and a p-type impurity layer 17, as shown in FIG. 5.

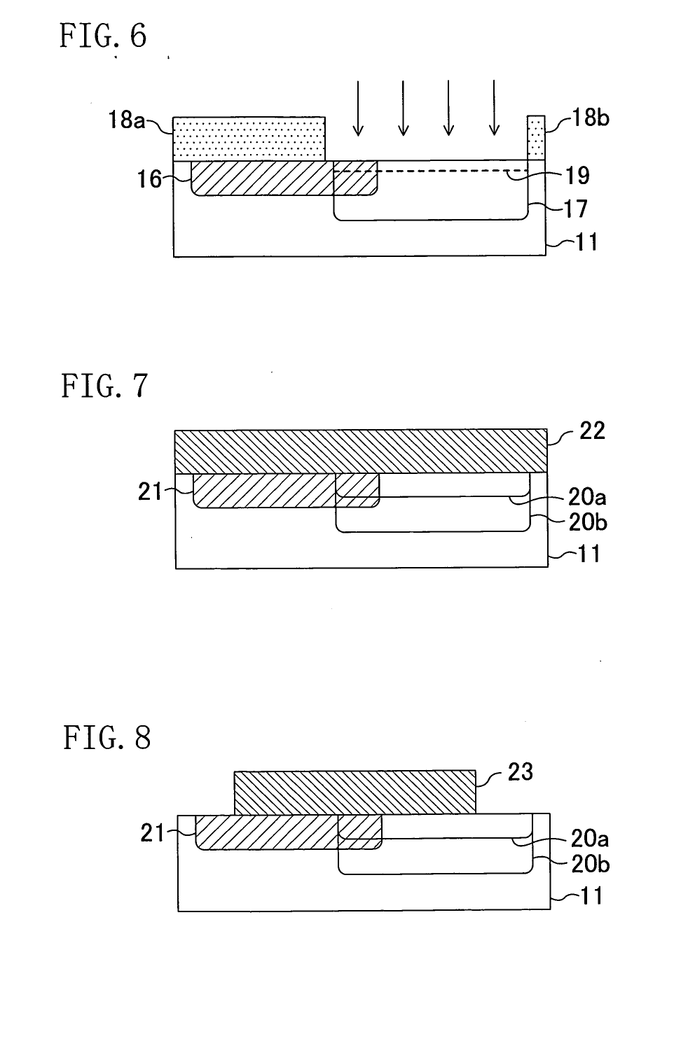

Thereafter, as shown in FIG. 6, resist films 18a and 18b of which part is opened correspondingly to the anode region are formed and patterned on the semiconductor substrate 11, and then, a p-type impurity 19 such as BF₂ is ion implanted into the anode region of the semiconductor substrate 11 with the use of the resist films 18a and 18b as a mask. As to the conditions for the ion implantation, the dose amount is set to, for example, approximately 7.0×10¹⁴ to 3.0×10¹⁵ cm⁻² and the acceleration energy is set to, for example, approximately 50 keV. In other words, the ion implantation of the p-type impurity 19 is carried out at concentration higher than the ion implantation of the p-type impurity 15.

Next, as shown in FIG. 7, after the resist films 18a and 18b are removed, an insulting film 22 formed of a BPSG (boro-phospho silicate glass) film or the like having a film thickness of, for example, approximately 100 nm to 2 μm is deposited on the semiconductor substrate 11, and then, the semiconductor substrate 11 is subjected to thermal treatment at a temperature of, for example, approximately 900° C. Whereby, the implanted p-type impurity 19 is diffused while the n-type impurity in the n-type impurity layer 16 and the p-type impurity in the p-type impurity layer 17 are re-diffused to form an n-type impurity layer 21 in the cathode region and a p-type impurity layer 20a (an upper layer) and a p-type impurity layer 20b (a lower layer) in the anode region. The diffusion depth of the n-type impurity layer 21 is deeper than that of the n-type impurity layer 16, and the diffusion depth of the p-type impurity layer 20b is deeper than that of the p-type impurity layer 17. The n-type impurity concentration distribution of the n-type impurity layer 21 is defined dominantly by a concentration profile having, for example, a peak concentration of approximately 1×10²⁰ to 5×10²⁰ cm⁻³ at the substrate surface and a diffusion depth of approximately 0.3 to 0.5 μm. The p-type impurity concentration distribution of the p-type impurity layer 20b is defined dominantly by a concentration profile having, for example, a peak concentration of approximately 7×10¹⁸ to 3×10¹⁹ cm⁻³ at the substrate surface and a diffusion depth of approximately 0.6 to 0.9 μm. The p-type impurity concentration distribution of the p-type impurity layer 20a is defined dominantly by a concentration profile having, for example, a peak concentration of approximately 3×10¹⁹ to 1×10²⁰ cm⁻³ at the substrate surface and a diffusion depth of approximately 0.3 to 0.5 μm. Wherein, the n-type impurity concentration distribution of the n-type impurity layer 21 and the p-type impurity distributions of the p-type impurity layers 20a and 20b overlap with each other in the range of approximately 1 to 2 μm in the horizontal direction. Also, the pn junction part (a part where the n-type impurity concentration and the p-type impurity concentration are in equilibrium) of the n-type impurity layer 21 and the p-type impurity layers 20a and 20b has an impurity concentration of approximately 1×10¹⁸ to 5×10¹⁸ cm⁻³.

Subsequently, as shown in FIG. 8, a resist film (not shown in the drawings) for covering the pn junction part is formed and patterned on the insulating film 22, and then, the insulating film 22 is etched using the resist film as a mask to form an insulating film 23 for covering the pn junction part of the Zener diode.

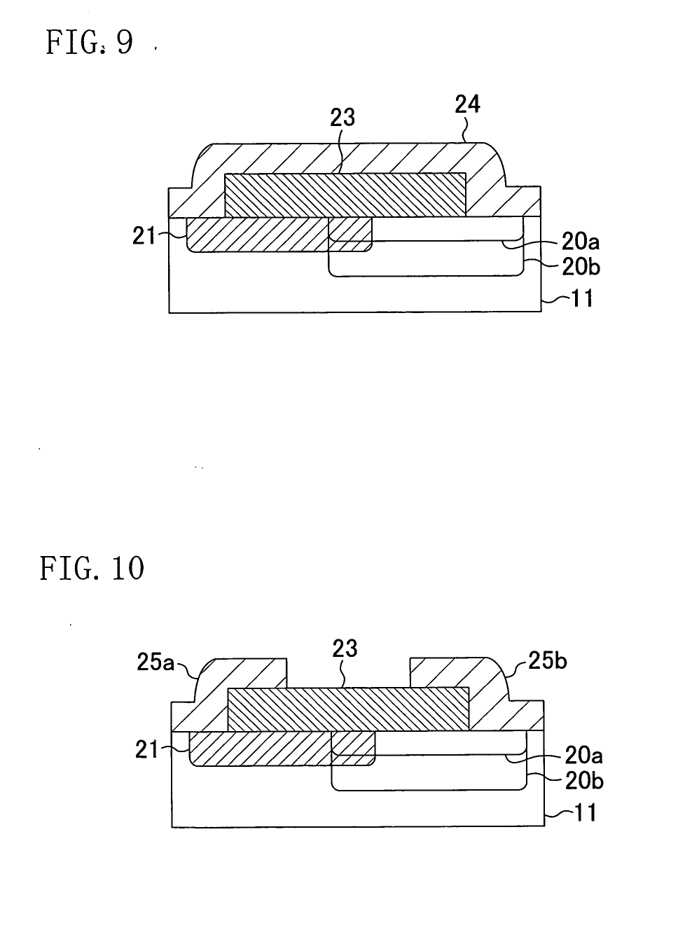

Thereafter, as shown in FIG. 9, an Al—Si—Cu alloy film 24 of which main component is Al is deposited on the semiconductor substrate 11 and the insulating film 23 thereon, and then, respective resist films (not shown in the drawings) for covering a cathode electrode formation region and an anode electrode formation region are formed and patterned on the alloy film 24. Then, the Al—Si—Cu alloy film 24 is etched using the resist film as a mask to form a cathode electrode 25a electrically connected with the n-type impurity layer 21 and an anode electrode 25b electrically connected with the p-type impurity layer 20a, as shown in FIG. 10.

The Zener diode manufacturing method of the present embodiment as described above attains a Zener diode having the same structure as that in the present embodiment shown in FIG. 1 and FIG. 2.

In the Zener diode manufacturing method of the present embodiment, the p-type impurity layer 20b is formed so as to have deep diffusion depth and low impurity concentration, thereby forming the low-concentration pn junction part, on which leakage current concentrates, reducing leakage current. Further, the formation of the p-type impurity layer 20a having shallow diffusion depth and high concentration in the vicinity of the substrate surface in the anode region lowers both the resistance of the anode region and the contact resistance between the anode region and the electrode.

### Embodiment 2

A semiconductor device and a method for manufacturing it according to Embodiment 2 of the present invention will be described below with reference to the accompanying drawings.

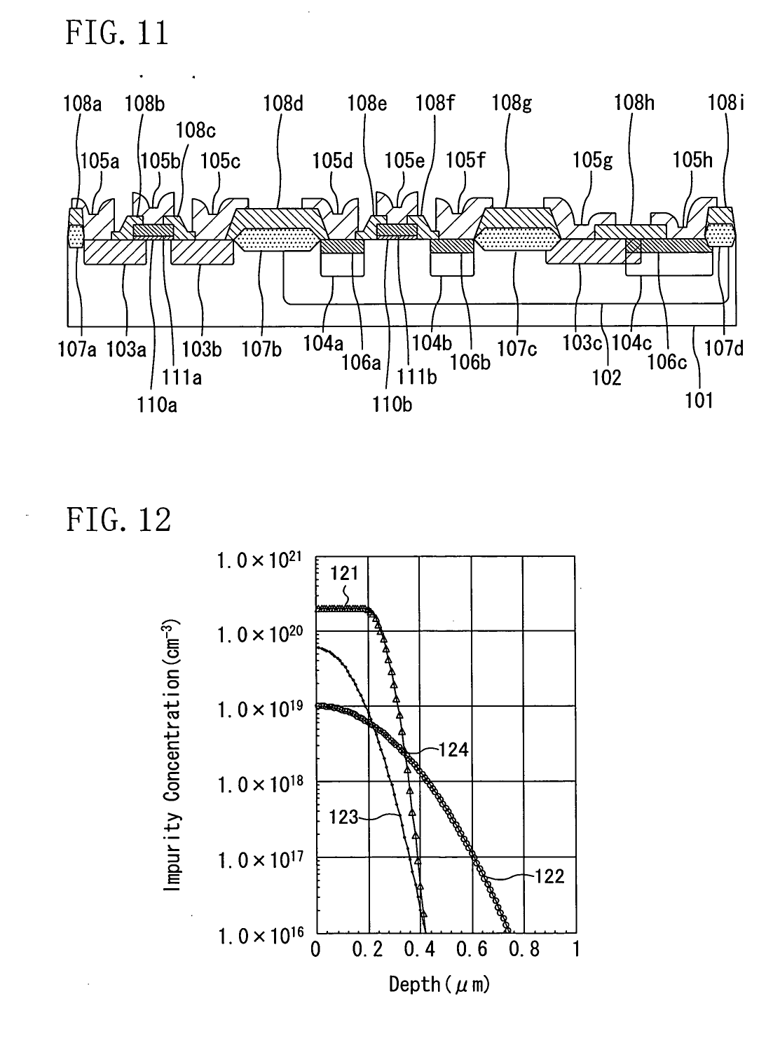

FIG. 11 is a section showing a structure of a semiconductor device according to Embodiment 2, specifically, a semiconductor device in which a CMOS circuit and a Zener diode are hybrided on a single semiconductor substrate.

As shown in FIG. 11, element isolation insulting films 107a to 107d are formed on a semiconductor substrate 101 formed of, for example, a p-type silicon substrate so that the semiconductor substrate 101 is defined into an n-channel filed effect transistor formation region, a p-channel field effect transistor formation region, and a Zener diode formation region. The element isolation insulating films 107a to 107d are covered with interlayer insulating films 108a, 108d, 108g, and 108i, respectively.

An n⁺ source region 103a and an n⁺ drain region 103b are formed in the surface portion in the n-channel field effect transistor formation region of the semiconductor substrate 101. On the region between the n⁺ source region 103a and the n⁺ drain region 103b of the semiconductor substrate 101, a gate electrode 111a is arranged with a gate dielectric film 110a interposed. The respective side faces of the gate electrode 111a are covered with interlayer insulting films 108b and 108c. A source electrode wiring 105a electrically connected with the n⁺ source region 103a is formed on the n⁺ source region 103a, a gate electrode wiring 105b electrically connected with the gate electrode 111a is formed on the gate electrode 111a, and a drain electrode wiring 105c electrically connected with the n⁺ drain region 103b is formed on the n⁺ drain region 103b.

In the semiconductor substrate 101, an n-type semiconductor region 102 is formed which includes the p-channel field effect transistor formation region and the Zener diode formation region and has an impurity concentration of, for example, approximately 2×10¹⁶ cm⁻³.

A p⁺ source region 104a (a lower layer), a p⁺ source region 106a (an upper layer), a p⁺ drain region 104b (a lower layer), and p⁺ drain region 106b (an upper layer) are formed in the surface portion of the p-channel field effect transistor formation region in the n-type semiconductor region 102. A gate electrode 111b is arranged on the region between the p⁺ source regions 104a and 106a and the p⁺ drain regions 104b and 106b in the p-channel field effect transistor formation region in the n-type semiconductor region with a gate dielectric film 110b interposed. The respective side faces of the gate electrode 111b are covered with interlayer insulating films 108e and 108f. A source electrode wiring 105d electrically connected with the p⁺ source region 106a is formed on the p⁺ source region 106a, a gate electrode wiring 105e electrically connected with the gate electrode 111b is formed on the gate electrode 111b, and a drain electrode wiring 105f electrically connected with the p⁺ drain region 106b is formed on the p⁺ drain region 106b.

In the Zener diode formation region in the n-type semiconductor region 102, an n-type impurity layer 103c having impurity concentration higher than the n-type semiconductor region 102 is formed in a cathode region and a p-type impurity layer 104c (a lower layer) and a p-type impurity layer 106c (an upper layer) are formed in an anode region in the Zener diode formation region so as to form pn junction with the n-type impurity layer 103c. In the present embodiment, the n-type impurity layer 103c is formed in the same step as the step of forming the n⁺ source region 103a and the n⁺ drain region 103b of the n-channel filed effect transistor. The p-type impurity layer 104c is formed in the same step as the step of forming the p⁺ source region 104a and the p⁺ drain region 104b of the p-channel filed effect transistor. As well, the p-type impurity layer 106c is formed in the same step as the step of forming the p⁺ source region 106a and the p⁺ drain region 106b of the p-channel filed effect transistor. An interlayer insulting film 108h is formed so as to cover a junction part (the pn junction) of the n-type impurity layer 103c and the p-type impurity layers 104c and 106c. A cathode electrode wiring 105g electrically connected with the n-type impurity layer 103c is formed on a part of the n-type impurity layer 103c where the interlayer insulting film 108h is not formed. An anode electrode wiring 105h electrically connected with the p-type impurity layer 106c is formed on a part of the p-type impurity layer 106c where the interlayer insulating film 108h is not formed. Accordingly, the pn junction part is located between the cathode electrode wiring 105g and the anode electrode wiring 105h.

In the present embodiment, each n-type impurity concentration distribution of the n⁺ source region 103a and the n⁺ drain region 103b of the n-channel field effect transistor and the n-type impurity layer 103c of the Zener diode is defined dominantly by a concentration profile of which peak concentration at the substrate surface portion is approximately 1×10²⁰ to 5×10²⁰ cm⁻¹ and of which diffusion depth is approximately 0.3 to 0.5 μm, for example. Each p-type impurity concentration distribution of the p⁺ source region 104a and the p⁺ drain region 104b of the p-channel field effect transistor and the p-type impurity layer 104c of the Zener diode is defined dominantly by a concentration profile of which peak concentration at the substrate surface portion is approximately 7×10¹⁸ to 3×10¹⁹ cm⁻³ and of which diffusion depth is approximately 0.6 to 0.9 μm, for example. Each p-type impurity concentration distribution of the p⁺ source region 106a and the p⁺ drain region 106b of the p-channel field effect transistor and the p-type impurity layer 106c of the Zener diode is defined dominantly by a concentration profile of which peak concentration at the substrate surface portion is approximately 3×10¹⁹ to 1×10²⁰ cm⁻³ and of which diffusion depth is approximately 0.3 to 0.5 μm, for example. In the Zener diode, the n-type impurity concentration distribution of the n-type impurity layer 103c and the p-type impurity concentration distributions of the p-type impurity layers 104c and 106c overlap with each other in the range of approximately 1 to 2 μm in the horizontal direction. Further, the impurity concentration at the pn junction part of the n-type impurity layer 103c and the p-type impurity layers 104c and 106c (where the n-type impurity concentration is balance with the p-type impurity concentration) is approximately 1×10¹⁸ to 5×10¹⁸ cm⁻³, for example.

In the present embodiment, the interlayer insulating films 108a to 108i are formed of BPSG films having a thickness of approximately 100 nm to 2 μm, for example. The cathode electrode wiring 105g and the anode electrode wiring 105h are made of Al—Si—Cu alloy of which main component is Al, for example. The source electrode wiring 105a, the gate electrode wiring 105b, the drain electrode wiring 105c, the source electrode wiring 105d, the gate electrode wiring 105e, and the drain electrode wiring 105f are made of Al—Si—Cu alloy similar to the cathode electrode wiring 105g and the anode electrode wiring 105h.

The first feature of the present embodiment lies in that in the Zener diode, the p-type semiconductor region (the anode region) formed of the p-type impurity layer 104c and the p-type impurity layer 106c has an impurity concentration distribution which is a combination of a first p-type impurity concentration distribution (defining the impurity concentration distribution of the p-type impurity layer 104c) having first diffusion depth and first peak concentration and a second p-type impurity concentration distribution (defining the impurity concentration distribution of the p-type impurity layer 106c) having second diffusion depth shallower than the first diffusion depth and second peak concentration higher than the first peak concentration. Wherein, the first p-type impurity concentration distribution is higher than the second p-type impurity concentration distribution in the concentration at the pn junction part.

In the present embodiment, the region where the concentration of the first p-type impurity concentration distribution is higher than the concentration of the second p-type impurity concentration distribution serves as the p-type impurity layer 104c while the region where the concentration of the second p-type impurity concentration distribution is higher than the concentration of the first p-type impurity concentration distribution serves as the p-type impurity layer 106c. In this case, the pn junction part is a junction part of the low-concentration p-type impurity layer 104c and the n-type impurity layer 103c. The second p-type impurity concentration distribution may not reach the pn junction part.

The second feature of the present embodiment lines in that the n-type impurity layer 103c of the Zener diode is formed in the same step as the step of forming the n⁺ source region 103a and the n⁺ drain region 103b of the n-channel field effect transistor, the p-type impurity layer 104c of the Zener diode is formed in the same step as the step of forming the p⁺ source region 104a and the p⁺ drain region 104b of the p-channel field effect transistor, and the p-type impurity layer 106c of the Zener diode is formed in the same step as the step of forming the p⁺ source region 106a and the p⁺ drain region 106b of the p-channel field effect transistor.

FIG. 12 shows each example of the concentration profile of the n-type impurity layer (in the cathode region) 103c and the concentration profiles of the p-type impurity layers (in the anode region) 104c and 106c of the Zener diode. Wherein, in FIG. 12, reference numeral 121 denotes the concentration profile of the n-type impurity layer 103c, that is, the n-type impurity concentration distribution, 122 denotes the first p-type impurity concentration distribution that defines the concentration profile of the p-type impurity layer 104c, 123 denotes the second p-type impurity concentration distribution that defines the concentration profile of the p-type impurity layer 106c, and 124 denotes the impurity concentration at the pn junction part.

In the semiconductor integrated circuit as described above in the present embodiment, the concentration at the pn junction part of the Zener diode is defined by the p-type impurity layer 104c in the anode region, which has low concentration and deep diffusion depth. Accordingly, even in the case where the impurity layers are formed by low-temperature thermal treatment for the purpose of element size miniaturizing, the pn junction part, on which leakage current concentrates, can have low impurity concentration (specifically, approximately 1×10¹⁸ to 5×10¹⁸ cm⁻³) compared with a conventional one, resulting in a reduction in leakage current of the Zener diode. This prevents an increase in concentration at the pn junction part by low-temperature thermal treatment, resulting in implementation of further element size miniaturization with the impurity diffusion restrained. Further, the impurity layers in the cathode region and the anode region of the Zener diode are formed in the same step as the step of forming the impurity layers in the source regions and the drain regions of the CMOS circuit, enabling hybridization with the Zener diode and suppression of an increase in number of manufacturing steps.

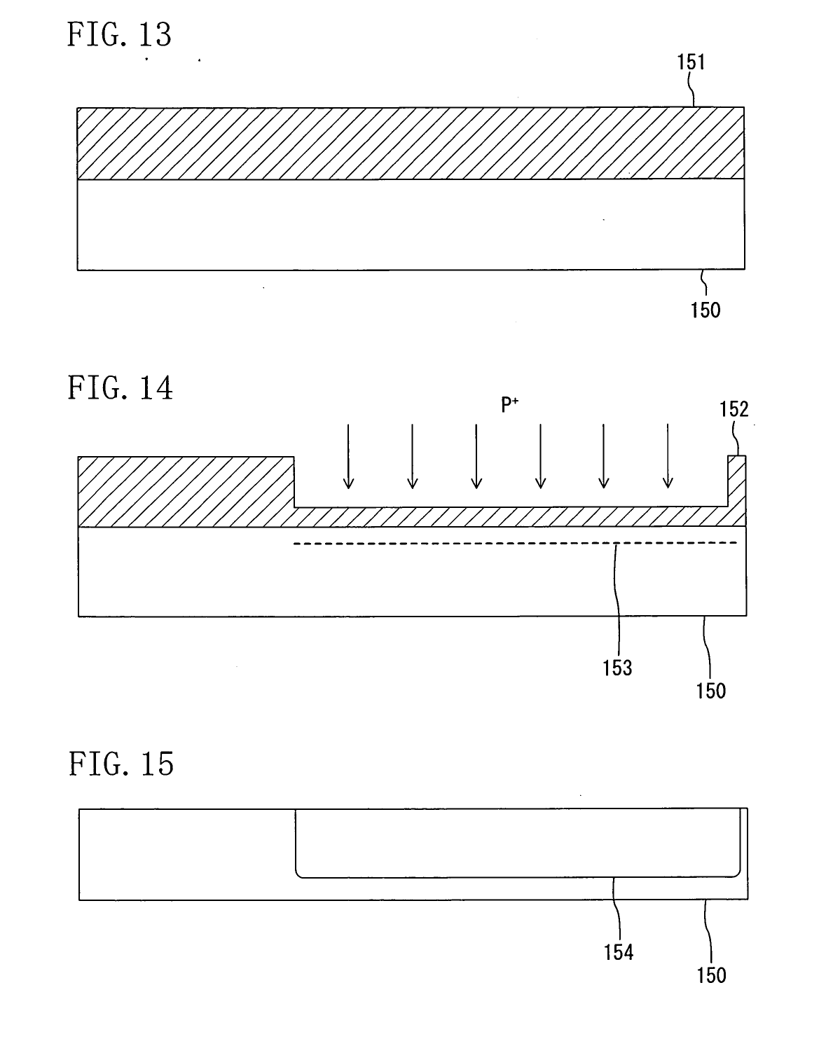

A semiconductor device manufacturing method according to Embodiment 2 will be described below with reference to FIG. 13 to FIG. 24.

First, as shown in FIG. 13, an SiO₂ film 151 is formed on a semiconductor substrate 150 formed of a p-type silicon substrate. Then, a resist film (not shown in the drawings) of which predetermined region is opened is formed and pattered on the SiO₂ film 151, the SiO₂ film 151 is etched using the resist film as a mask, and then, the resist film is removed.

Next, as shown in FIG. 14, an n-type impurity 153 such as P is ion implanted into the predetermined region of the semiconductor substrate 150 with the use of a part of the SiO₂ film 151 of which the predetermined region is etched so as to have smaller thickness, that is, an SiO₂ film pattern 152 as a mask. As to the conditions for the ion implantation, the dose amount is set to, for example, approximately 9.0×10¹² to 1.0×10¹³ cm⁻² and the acceleration energy is set to, for example, approximately 150 keV.

Subsequently, as shown in FIG. 15, the semiconductor substrate 150 is subjected to thermal treatment at a temperature of, for example, approximately 1200° C. for approximately 10 to 11 hours in an atmosphere of, for example, N₂ to diffuse the implanted n-type impurity 153, thereby forming an n-type impurity layer 154 having an impurity concentration distribution of which diffusion depth is approximately 7 to 9 μm and of which concentration is, for example, 1.0×10¹⁶ to 3.0×10¹⁶ cm⁻³ uniformly in the depth direction from the substrate surface.

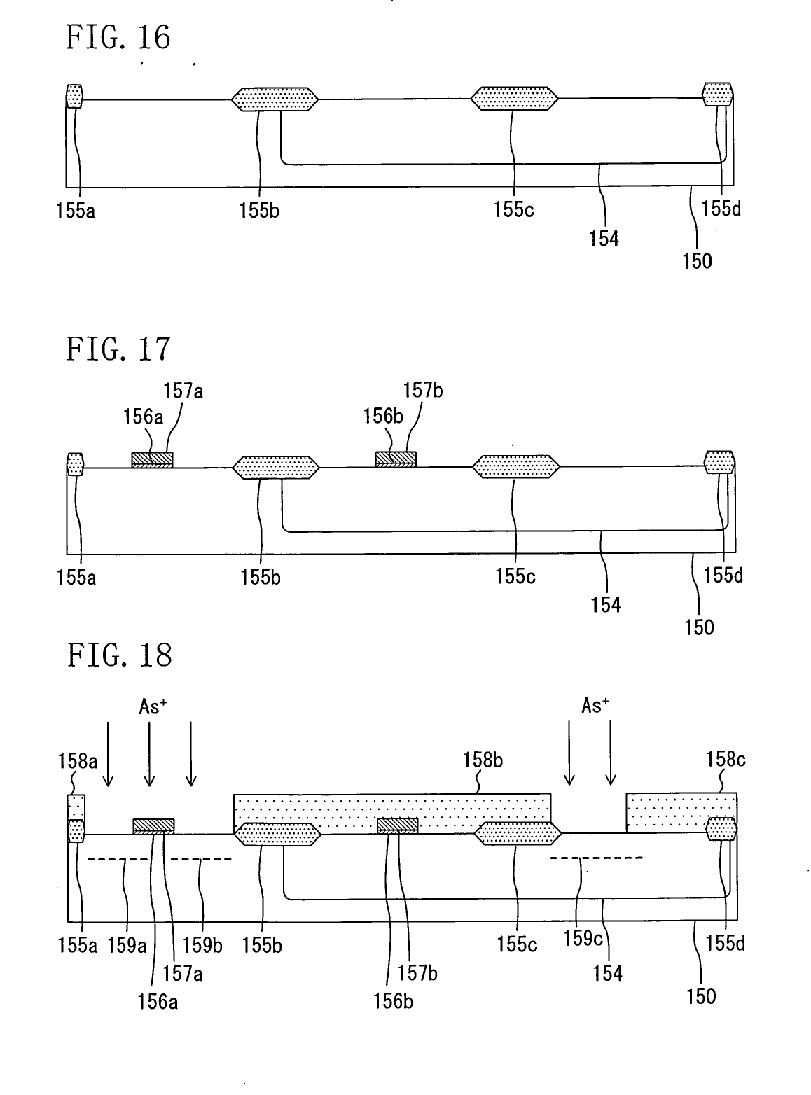

Thereafter, after the SiO₂ film pattern 152 on the substrate surface is removed, an Si₃N₄ film (not shown in the drawings) is deposited on the semiconductor substrate 150 and a resist film (not shown in the drawings) for covering a predetermined region of the Si₃N₄ film is formed and patterned on the Si₃N₄ film. Then, the Si₃N₄ film is etched using the resist film as a mask, element isolation insulating films 155a to 155d formed of, for example, SiO₂ films are formed using the patterned Si₃N₄ film as a mask, as shown in FIG. 16, and then, the Si₃N₄ film is removed. Whereby, the semiconductor substrate 150 is defined into an n-channel field effect transistor formation region, a p-channel field effect transistor formation region, and a Zener diode formation region. Wherein, the p-channel field effect transistor formation region and the Zener diode formation region are located within the n-type impurity layer 154.

Next, after an insulating film to be a gate dielectric film and a conductive film (a polysilicon film, for example) to be a gate electrode are deposited on the semiconductor substrate 150, a resist film (not shown in the drawings) for covering a gate electrode formation region is formed and patterned on the polysilicon film and the insulating film and the polysilicon film are etched using the resist film as a mask. Thus, as shown in FIG. 17, a gate electrode 157a is formed in the n-channel filed effect transistor formation region of the semiconductor substrate 150 with a gate dielectric film 156a interposed while a gate electrode 157b is formed on the p-channel field effect transistor formation region of the n-type impurity layer 154 with a gate dielectric film 156b interposed.

Subsequently, as shown in FIG. 18, resist films 158a to 158c of which parts are opened correspondingly to the n-channel field effect transistor formation region and a cathode region in the Zener diode formation region are formed on the semiconductor substrate 150, an n-type impurity 159a to 159c such as As is ion implanted into the source region and the drain region of the n-channel filed effect transistor and the cathode region of the Zener diode with the use of the resist films 158a to 158c as a mask. As to the condition for the ion implantation, the dose amount is set to, for example, approximately 5.0×10¹⁵ to 1.0×10¹⁶ cm⁻² and the acceleration energy is set to, for example, approximately 60 keV.

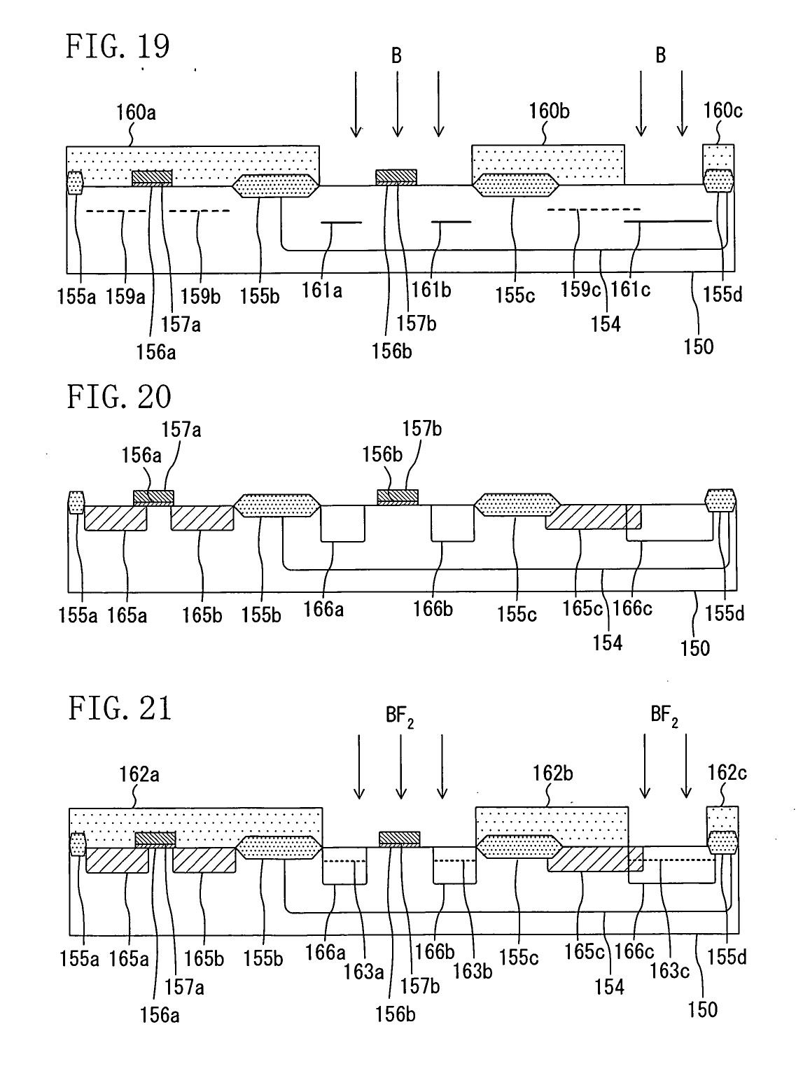

Thereafter, after the resist films 158a to 158c are removed, resist films 160a to 160c of which parts are opened correspondingly to the p-channel filed effect transistor formation region and an anode region of the Zener diode formation region are formed on the semiconductor substrate 150, as shown in FIG. 19. Then, a p-type impurity 161a to 161c such as B is ion implanted into the source region and the drain region of the p-channel field effect transistor and the anode region of the Zener diode with the use of the resist films 160a to 160c as a mask. As to the conditions for the ion implantation, the dose amount is set to, for example, approximately 1.0×10¹⁴ to 5.0×10¹⁴ cm⁻² and the acceleration energy is set to, for example, approximately 50 keV.

Next, after the resist films 160a to 160c are removed, the semiconductor substrate 150 is subjected to thermal treatment at a temperature of, for example, approximately 1000° C. for approximately 20 to 30 minutes in an atmosphere of, for example, N₂ to diffuse the implanted n-type impurity 159a to 159c and the implanted p-type impurity 161a to 161c. Thus, n-type impurity layers 165a to 165c are formed in the source region and the drain region of the n-channel field effect transistor and the cathode region of the Zener diode, respectively, while p-type impurity layers 166a to 166c are formed in the source region and the drain region of the p-channel field effect transistor and the anode region of the Zener diode, respectively, as shown in FIG. 20.

Subsequently, as shown in FIG. 21, resist films 162a to 162c of which parts are opened correspondingly to the p-channel field effect transistor formation region and the anode region of the Zener diode formation region are formed on the semiconductor substrate 150. Then, a p-type impurity 163a to 163c such as BF₂ is ion implanted into the source region and the drain region of the p-channel field effect transistor and the anode region of the Zener diode with the use of the resist films 162a to 162c as a mask. As to the conditions for the ion implantation, the dose amount is set to, for example, approximately 7.0×10¹⁴ to 3.0×10¹⁵ cm⁻² and the acceleration energy is set to, for example, approximately 50 keV. In other words, the ion implantation of the p-type impurity ion 163a to 163c is carried out at concentration higher than the ion implantation of the p-type impurity 161a to 161c.

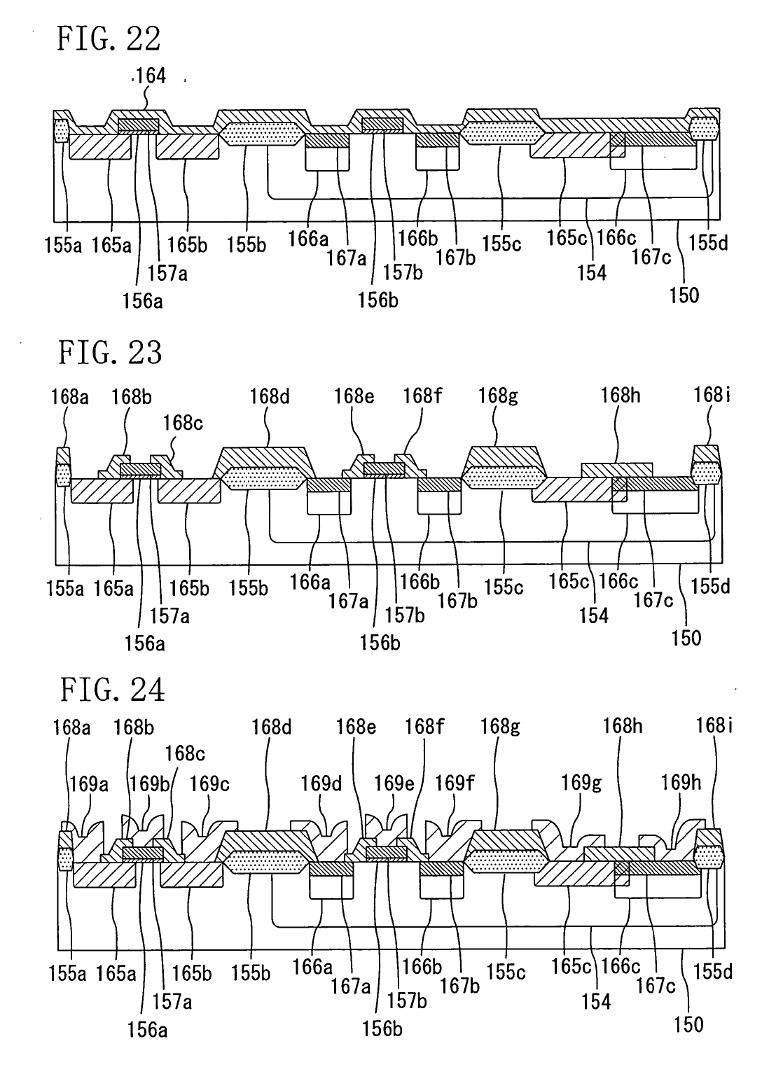

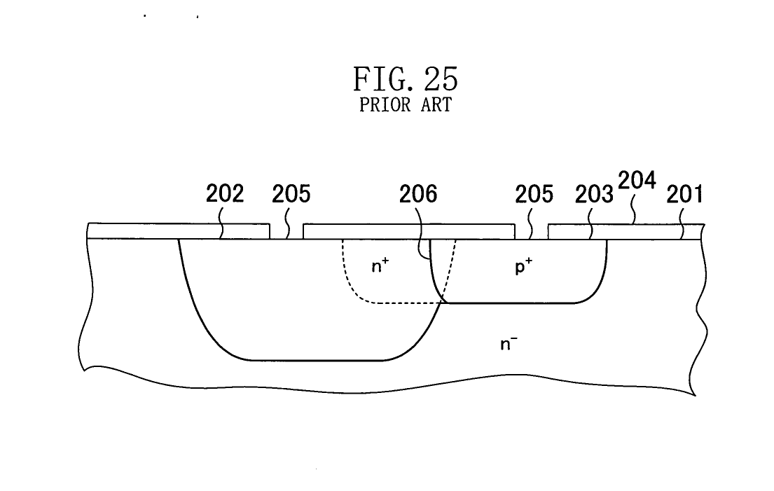

Thereafter, as shown in FIG. 22, after the resist films 162a to 162c are removed, a layered film of, for example, an SiO2 film and a BPSG film is deposited as an interlayer insulating film 164 on the semiconductor substrate 150 and thermal treatment at a temperature of, for example, approximately 900° C. is carried out to the semiconductor substrate 150 to allow the surface of the interlayer insulating film 164 to be planerized. This thermal treatment also allows the implanted p-type impurity 163a to 163c to be diffused while allowing the n-type impurity in the n-type impurity layers 165a to 165c and the p-type impurity in the p-type impurity layers 166a to 166c to be re-diffused. This deepens further the diffusion depth of the n-type impurity layers 165a and 165b respectively in the source region and the drain region of the n-channel field effect transistor, the diffusion depth of the p-type impurity layers 166a and 166b respectively in the source region and the drain region of the p-channel filed effect transistor, the diffusion depth of the n-type impurity layer 165c in the cathode region of the Zener diode, and the diffusion depth of the p-type impurity layer 166c in the anode region of the Zener diode. Further, p-type impurity layers 167a and 167b having diffusion depth and concentration shallower and higher than the p-type impurity layers 166a and 166b are respectively formed in the source region and the drain region of the p-channel field effect transistor while a p-type impurity layer 167c having diffusion depth and concentration shallower and higher than the p-type impurity layer 166c is formed in the anode region of the Zener diode. At this point, the n-type impurity concentration distributions of the n-type impurity layers 165a to 165c respectively in the source region and the drain region of the n-channel field effect transistor and the cathode region of the Zener diode are defined dominantly by a concentration profile having, for example, a peak concentration of approximately 1×10²⁰ to 5×10²⁰ cm⁻³ at the substrate surface portion and a diffusion depth of approximately 0.3 to 0.5 μm. The p-type impurity concentration distributions of the p-type impurity layers 166a to 166c respectively in the source region and the drain region of the p-channel field effect transistor and the anode region of the Zener diode are defined dominantly by a concentration profile having, for example, a peak concentration of approximately 7×10¹⁸ to 3×10¹⁹ cm⁻³ at the substrate surface portion and a diffusion depth of approximately 0.6 to 0.9 μm. Also, the p-type impurity concentration distributions of the p-type impurity layers 167a to 167c in the source region and the drain region of the p-channel field effect transistor and the anode region of the Zener diode are defined dominantly by a concentration profile having, for example, a peak concentration of approximately 3×10¹⁹ to 1×10²⁰ cm⁻³ at the substrate surface portion and a diffusion depth of approximately 0.3 to 0.5 μm. In the Zener diode, the n-type impurity concentration diffusion distribution of the n-type impurity layer 165c in the cathode region and the p-type impurity concentration distributions of the p-type impurity layers 166c and 167c in the anode region overlap with each other in the range of approximately 1 to 2 μm in the horizontal direction. Further, the impurity concentration at the pn junction part of the n-type impurity layer 165c and the p-type impurity layers 166c and 167c (where the n-type impurity concentration and the p-type impurity concentration are in equilibrium) is approximately 1×10¹⁸ to 5×10¹⁸ cm⁻³, for example.

Next, on the interlayer insulating film 164, a resist film (not shown in the drawings) is formed and patterned of which predetermined regions are opened (specifically, regions corresponding to: each contact region in contact with the source region, the gate electrode, and the drain region of the n-channel field effect transistor; each contact region in contact with the source region, the gate electrode, and the drain region of the p-channel field effect transistor; and each contact region in contact with the cathode region and the anode region of the Zener diode). Then, the interlayer insulating film 164 is etched using the resist film as a mask to form interlayer insulating films 168a, 168d, 168g, and 168i respectively for covering the element isolation insulating films 155a to 155d, interlayer insulating films 168b and 168c for covering the respective side faces of the gate electrode 157a, interlayer insulating films 168e and 168f for covering the respective side faces of the gate electrodes 157b, and an interlayer insulating film 168h for covering the pn junction part, as shown in FIG. 23.

Subsequently, after an Al—Si—Cu alloy film of which main component is Al is deposited on the semiconductor substrate 150 and the interlayer insulating films 168a to 168i thereon, a resist film (not shown in the drawings) is formed and patterned on the alloy film for covering predetermined regions (specifically, regions corresponding to: each contact region in contact with the source region, the gate electrode, and the drain region of the n-channel field effect transistor; each contact region in contact with the source region, the gate electrode, and the drain region of the p-channel field effect transistor; and each contact region in contact with the cathode region and the anode region of the Zener diode). Then, the alloy film is etched using the resist film as a mask. Thus, as shown in FIG. 24, in the n-channel field effect transistor, a source electrode wiring 169a electrically connected with the n-type impurity layer 165a is formed on the n-type impurity layer 165a in the source region, a gate electrode wiring 169b electrically connected with the gate electrode 157a is formed on the gate electrode 157a, and a drain electrode wiring 169c electrically connected with the n-type impurity layer 165b is formed on the n-type impurity layer 165b in the drain region. In the p-channel field effect transistor, a source electrode wiring 169d electrically connected with the p-type impurity layer 167a is formed on the p-type impurity layer 167a in the source region, a gate electrode wiring 169e electrically connected with the gate electrode 157b is formed on the gate electrode 157b, and a drain electrode wiring 169f electrically connected with the p-type impurity layer 167b is formed on the p-type impurity layer 167b in the drain region. As well, in the Zener diode, a cathode electrode 169g electrically connected with the n-type impurity layer 165c is formed on the n-type impurity layer 165c in the cathode region and an anode electrode wiring 169h electrically connected with the p-type impurity layer 167c is formed on the p-type impurity layer 167c in the anode region.

According to the semiconductor device manufacturing method in the present embodiment as described above, the same structure can be obtained as that of the semiconductor device of the present embodiment shown in FIG. 11 and FIG. 12, that is, a semiconductor integrated circuit device in which a Zener diode and a CMOS circuit or the like are hybrided on a single substrate.

Further, in the semiconductor device manufacturing method in the present embodiment, the p-type impurity layer 104c (166c) having deep diffusion depth and low concentration in the anode region of the Zener diode is formed to allow the pn junction part, on which leakage current concentrates, to have low concentration, reducing leakage current of the Zener diode. This prevents an increase in concentration of the pn junction part by low-temperature thermal treatment, and hence, the p⁺ source region and the p⁺ drain region of the p-channel filed effect transistor can be formed by low-temperature thermal treatment, implementing further element size miniaturization with impurity diffusion restrained. Moreover, formation of the p-type impurity layer 106c (167c) having shallow diffusion depth and high concentration at a vicinity of the substrate surface in the anode region of the Zener diode lowers both the resistance of the anode region and the contact resistance between the anode region and the electrode. In addition, the impurity layers in the cathode region and the anode region of the Zener diode are formed in the same step as the step of forming the impurity layers in the source regions and the drain regions of the CMOS circuit, enabling hybridization of the Zener diode with the CMOS circuit and preventing an increase in number of manufacturing steps.

What is claimed is:

1. A semiconductor device comprising a semiconductor substrate and a Zener diode formed on the semiconductor substrate,
wherein the Zener diode includes:
a first conductivity type semiconductor region and a second conductivity type semiconductor region which are formed so as to form pn junction in the semiconductor substrate;
an insulating film for covering a junction part of the first conductivity type semiconductor region and the second conductivity type semiconductor region;
a first electrode formed on the first conductivity type semiconductor region so as to be electrically connected with the first conductivity type semiconductor region; and
a second electrode formed on the second conductivity type semiconductor region so as to be electrically connected with the second conductivity type semiconductor region,
wherein the second conductivity type semiconductor region has an impurity concentration distribution which is a combination of a first impurity concentration diffusion distribution having first diffusion depth and first peak concentration and a second impurity diffusion distribution having second diffusion depth shallower than the first diffusion depth and second peak concentration higher than the first peak concentration, and
the first impurity concentration distribution is higher than the second impurity concentration distribution in concentration at the junction part.

2. A method for manufacturing a semiconductor device having a Zener diode formed on a semiconductor substrate, comprising:
a step (a) of ion implanting a first conductivity type impurity into a cathode region of the Zener diode in the semiconductor substrate;
a step (b) of ion implanting a second conductivity type impurity into an anode region of the Zener diode in the semiconductor substrate;
a step (c) of forming a first conductivity type impurity layer and a second conductivity type impurity layer by diffusing by thermal treatment the first conductivity type impurity implanted in the step (a) and the second conductivity type impurity implanted in the step (b);
a step (d) of ion implanting a second conductivity type impurity into the anode region at concentration higher than that in the step (b); and
a step (e) of diffusing the second conductivity type impurity implanted in the step (d) by thermal treatment to form an additional second conductivity type impurity layer and to deepen diffusion depth of the second conductivity type impurity layer.

3. A semiconductor device in which a first field effect transistor, a second field effect transistor, and a Zener diode are formed on a second conductivity type single semiconductor substrate including a first conductivity type semiconductor region, comprising:
a first conductivity type source region and a first conductivity type drain region which are formed in a surface portion in a region of the second conductivity type semiconductor substrate where the first filed effect transistor is formed;
a first source electrode formed on the first conductivity type source region so as to be electrically connected with the first conductivity type source region;
a first drain electrode formed on the first conductivity type drain region so as to be electrically connected with the first conductivity type drain region;
a first gate electrode formed on a region between the first conductivity type source region and the first conductivity type drain region of the semiconductor substrate with a dielectric film interposed;
a second conductivity type source region and a second conductivity type drain region which are formed in a surface portion of a region in the first conductivity type semiconductor region of the semiconductor substrate where the second field effect transistor is formed,
a second source electrode formed on the second conductivity type source region so as to be electrically connected with the second conductivity type source region;
a second drain electrode formed on the second conductivity type drain region so as to be electrically connected with the second conductivity type drain region;
a second gate electrode on a region between the second conductivity type source region and the second conductivity type drain region in the semiconductor substrate with a dielectric film interposed;
an additional first conductivity type semiconductor region formed in a region of the first conductivity type semiconductor region where the Zener diode is formed and having impurity concentration higher than the first conductivity type semiconductor region;
a second conductivity type semiconductor region formed in the region where the Zener diode is formed so as to form pn junction with the additional first conductivity type semiconductor region;
an insulating film for covering a junction part of the additional first conductivity type semiconductor region and the second conductivity type semiconductor region;
a first electrode formed on the additional first semiconductor region so as to be electrically connected with the additional first conductivity type semiconductor region; and
a second electrode formed on the second conductivity type semiconductor region so as to be electrically connected with the second conductivity type semiconductor region,
wherein each of the second conductivity type source region and the second conductivity type drain region of the second field effect transistor and the second conductivity type semiconductor region of the Zener diode has an impurity concentration distribution which is a combination of a first impurity concentration distribution having first diffusion depth and first peak concentration and a second impurity concentration distribution having second diffusion depth shallower than the first diffusion depth and second peak concentration higher than the first peak concentration, and
the first impurity concentration distribution is higher than the second impurity concentration distribution in concentration at the junction part of the Zener diode.

4. A method for manufacturing a semiconductor device in which a first filed effect transistor, a second field defect transistor, and a Zener diode are formed on a single semiconductor substrate, comprising:
a step (a) of ion implanting a first conductivity type impurity into a first conductivity type source region and a first conductivity type drain region of the first field effect transistor and a cathode region of the Zener diode in the semiconductor substrate;
a step (b) of ion implanting a second conductivity type impurity into a second conductivity type source region and a second conductivity type drain region of the second field effect transistor and an anode region of the Zener diode in the semiconductor substrate;
a step (c) of forming first conductivity type impurity layers and second conductivity type impurity layers by diffusing by thermal treatment the first conductivity type impurity implanted in the step (a) and the second conductivity type impurity implanted in the step (b);
a step (d) of ion implanting a second conductivity type impurity into the second conductivity type source region, the second conductivity type drain region, and the anode region at concentration higher than that in the step (b); and
a step (e) of diffusing the second conductivity type impurity implanted in the step (d) by thermal treatment to form additional second conductivity type impurity layers and to deepen diffusion depth of the second conductivity type impurity layers.
